(19) United States
(12) Patent Application Publication
(10) Pub. No.: US 2025/0306250 A1
(43) Pub. Date: Oct. 2, 2025

(54) MEMBER AND METHOD FOR MANUFACTURING THE SAME

(71) Applicant: CANON KABUSHIKI KAISHA, Tokyo (JP)

(72) Inventors: TAKAHITO CHIBANA, Tochigi (JP); HIDEO AKIBA, Tochigi (JP)

(21) Appl. No.: 19/088,773

(22) Filed: Mar. 24, 2025

(30) Foreign Application Priority Data
Mar. 26, 2024 (JP) 2024-050586

(51) Int. Cl. G02B 3/00; G02B 1/11; G02B 1/14; G02B 3/08

(52) U.S. Cl. CPC G02B 3/0056; G02B 1/11; G02B 1/14; G02B 3/08; G02B 2003/0093

(57) ABSTRACT

A member includes a base having a surface with an uneven structure, and a layer containing an oxide or a nitride over the uneven structure of the base. The layer has a higher carbon content at a surface than on an inside.

### BACKGROUND

### Technical Field

The present disclosure relates to a member and a method for manufacturing the member.

### Description of the Related Art

Members using light-transmitting bases, such as optical lenses and optical films, are required to exhibit reduced surface reflection. Such members have been known to be provided with a fine-uneven structure at the surface of the base to impart an antireflection function. Japanese Patent Laid-Open No. 2003-172808 discloses a technique to prevent water adsorption from degrading the antireflection function, in which a water-repellent coating is formed over the fine-uneven structure to repellent water droplets.

However, polytetrafluoroethylene water-repellent coatings, as disclosed in Japanese Patent Laid-Open No. 2003-172808, may exhibit low adhesion to fine-uneven structures, leading to pealing during the wiping of the member surface.

### SUMMARY

The present disclosure provides a member including a base having a surface with an uneven structure, and a layer containing an oxide or a nitride over the uneven structure of the base. The layer has a higher carbon content at a surface than on an inside.

Further features of the present disclosure will become apparent from the following description of exemplary embodiments with reference to the attached drawings.

### BRIEF DESCRIPTION OF THE DRAWINGS

FIG. 1 is a perspective view of an optical member according to a first embodiment.

FIG. 2 is a sectional view of the optical member according to the first embodiment.

FIG. 3 is a sectional view of an optical member according to a second embodiment.

FIG. 4 is a sectional view of a lens that is a modification of the second embodiment.

### DESCRIPTION OF THE EMBODIMENTS

Exemplary embodiments of the present disclosure will now be described in detail with reference to the drawings. In the drawings referenced in the description of the following embodiments and Examples, elements denoted with the same reference numeral have similar functions unless otherwise specified.

### First Embodiment

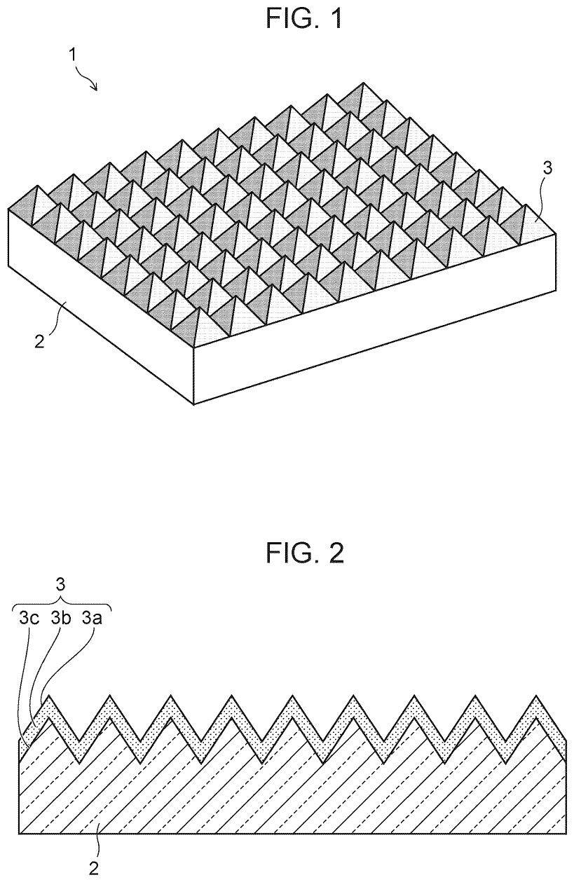

FIG. 1 is a perspective view of an optical member 1 according to a first embodiment. The optical member 1 includes a base 2 (light-transmitting base) that transmits visible light and has a surface with a fine-uneven structure, and a protective coating 3 (protective layer) over the surface of the fine-uneven structure.

### Optical Member

The fine-uneven structure has a plurality of protrusions that are formed so as to continuously reduce the refractive index from the respective bottoms toward the tips (toward the surface). Thus, an antireflection function is imparted to the surface of the optical member 1.

The fine-uneven structure is formed at a pitch less than or equal to the wavelengths of visible light, specifically at a pitch of 800 nm or less. The height of the fine-uneven structure is between 100 nm and 2000 nm, appropriately determined according to the pitch of the fine-uneven structure (intervals of the protrusions). For example, when the base 2 has a refractive index of 1.5 and is provided with a fine-uneven structure defined by quadrangular pyramidal protrusions, as illustrated in FIG. 1, the fine-uneven structure formed at a pitch of 400 nm produces an antireflection effect at a height of 200 nm or more. When a wider pitch is desired in the fine-uneven structure, the height can be increased. If the pitch of the fine-uneven structure is reduced, the height of the structure can be reduced, but the formation of the fine-uneven structure is difficult. In some embodiments, the pitch of the fine-uneven structure is 100 nm or more from the viewpoint of formation difficulty. The pitch and height of the fine-uneven structure can be determined from the viewpoint of the formation difficulty, water resistance, manufacturing costs, and the like.

Although the fine-uneven structure of the optical member in FIG. 1 has quadrangular pyramidal protrusions, the protrusions of the fine-uneven structure are not limited to quadrangular pyramidal shapes. The protrusions of the fine-uneven structure may be conical or bell-shaped as long as the refractive index changes continuously. From the viewpoint of resistance to breakage, the tips may be rounded.

### Base

The base 2 may be made of a light-transmitting resin. Such resins include polycarbonate resin, acrylate resin, and polyolefin resin. Other resins that can be used include polyester, triacetyl cellulose, cellulose acetate, polyethylene terephthalate, polypropylene, polystyrene, polymethyl methacrylate, ABS resin, polyphenylene oxide, polyurethane, polyethylene, and polyvinyl chloride. Also, unsaturated polyester resin, phenol resin, crosslinked polyurethane, crosslinked acrylic resin, and crosslinked saturated polyester resin are included.

### Formation of Fine-Uneven Structure

The fine-uneven structure at the surface of the base 2 may be formed by, but not limited to, shape transfer, such as injection molding or pressing. In the shape transfer, a stamper (mold) with a fine-uneven structure is made, and the fine-uneven structure is transferred to the surface of the base 2 using the stamper.

In such a method, the uneven profile of the stamper may be transferred by curing an active energy-curable resin composition by active energy irradiation. In this instance, the fine-uneven structure may be formed as a film (layer).

In the present embodiment, the base 2 is provided with a periodically fine-uneven profile by injection molding.

By using injection molding, the base 2 with a periodically fine-uneven structure can be produced inexpensively and in large quantities.

### Protective Coating

The protective coating 3 over the surface of the fine-uneven structure will be described with reference to FIG. 2. FIG. 2 is a sectional view of the optical member depicted in the perspective view of FIG. 1, taken along a plane including the tips of the fine-uneven structure, viewed in the normal to the plane.

As depicted in FIG. 2, the protective coating 3 covers the fine-uneven structure and includes a surface layer 3a, an internal portion 3b, and an interface layer 3c in contact with the fine-uneven structure. The protective coating 3 is made of an oxide film or a nitride film. The oxide film refers to a film containing an oxide as the main constituent and also contains impurities such as carbon and hydrogen. Similarly, the nitride film contains impurities such as carbon and hydrogen.

The oxide film may be made of any of the following materials: silicon oxide (SiO₂), aluminum oxide (Al₂O₃), tantalum oxide (Ta₂O₅), titanium oxide (TiO₂), niobium oxide (Nb₂O₅), and zirconium oxide (ZrO₂). Alternatively, yttrium oxide (Y₂O₃) or indium tin oxide (ITO) may be used. A mixture of these materials may be used. The nitride film may be made of any of the following materials: silicon nitride (SiN), titanium nitride (TiN), and aluminum nitride (AlN). A mixture of these materials may be used. Allowing for adsorption power to the resin, the protective coating 3 can particularly be a silicon oxide film.

In the present embodiment, the protective coating 3 can be a film including an oxide film or a nitride film. Such a protective coating is superior in adhesion to protective coatings using fluorine-containing materials. However, the surface of oxide or nitride films is generally hydrophilic. If the oxide or nitride protective coating 3 is formed by a conventional method, water resistance cannot be ensured.

Accordingly, in the present embodiment, the resistance of the protective coating 3 to water droplets is enhanced using the impurities such as carbon and hydrogen contained in the oxide or nitride film. More specifically, the protective coating 3 is formed so that the carbon content of the protective coating 3 is higher in the surface layer 3a than the internal portion 3b or the interface layer 3c. Thus, functional groups such as alkyl or methylene groups can be exposed at the surface in larger proportions at the surface layer 3a of the protective coating 3. Exposing functional groups such as alkyl groups at the surface reduces surface free energy compared to the case of not exposing such functional groups. This can increase the contact angle of the surface of the protective coating 3 with water, thereby enhancing the water resistance.

The composition of the surface layer 3a of the protective coating 3 can satisfy the relationship [Cₛ]/[Bₛ]≥0.5, wherein [Cₛ] represents the carbon content in the surface layer 3a, and [Bₛ] represents the oxygen or nitrogen content in the surface layer 3a. Consequently, the above-mentioned functional groups are sufficiently exposed to increase the contact angle, further enhancing the water resistance.

Also, [Cₙ]/[Bₙ]≤1.6 may hold, wherein [Cₙ] represents the carbon content in the internal portion 3b of the protective coating 3, and [Bₙ] represents the oxygen or nitrogen content of the internal portion 3b. Reducing the carbon content of the oxide or nitride film can inhibit the permeation of water vapor, further enhancing the water resistance.

Furthermore, [Cₖ]/[Bₖ]≤1.0 may hold, wherein [Cₖ] represents the carbon content in the interface layer 3c with the fine-uneven structure, and [Bₖ] represents the oxygen or nitrogen content in the interface layer 3c. Reducing the carbon content in the interface layer 3c increases the amount of the protective coating 3 bound to hydroxy groups in the surface of the fine-uneven structure, further enhancing adhesion. Although [Cₖ]/[Bₖ]=0 is beneficial in view of adhesion, [Cₖ]/[Bₖ]=0 is not necessary in consideration that the base 2 is resin. Resin expands and contracts greatly with temperature, and addition of carbon to the interface layer 3c can improve the resistance to such expansion and contraction. When the protective coating 3 binds to the hydroxy groups in the surface of the fine-uneven structure in a large proportion, temperature increase can cause expansion and contraction, potentially leading to cracks in the protective coating 3. The addition of carbon can reduce the amount of binding of the protective coating 3 with hydroxy groups at the interface, thus reducing the cracks in the protective coating 3 against the expansion and contraction of the resin. The carbon content in the interface layer 3c can be determined as appropriate from the viewpoint of how to address adhesion and temperature issues.

### Formation of Protective Coating

The protective coating 3 may be formed by, for example, atomic layer deposition (hereinafter also abbreviated to ALD) as disclosed in PCT Japanese Translation Patent Publication No. 2009-525406, sputtering, or vacuum deposition. In some embodiments, ALD is used in view of film formation on the fine-uneven structure. An ALD process will briefly be described below. First, a first layer is adsorbed to the surface on which the coating will be formed, using, for example, OH groups or other sites to which a precursor of the raw material gas can adsorb. At this time, the precursor is adsorbed to the surface at which OH groups are exposed, thereby forming a monolayer along the profile of the fine-uneven structure. Subsequently, the excess precursor that is not adsorbed is purged (removed). Then, an oxide or nitride molecular layer is formed using radicals, ozone, or a precursor that can oxidize or nitride the adsorbed precursor. Subsequently, the excess precursor is purged (removed). Thus, the ALD process repeats an ALD cycle of the following (a) to (d): (a) feeding a precursor of the raw material gas, (b) purging, (c) feeding radicals, ozone, or a precursor for oxidation or nitriding, and (d) purging, until reaching a desired thickness. For feeding each precursor, N₂ or Ar may be used as a carrier gas. ALD enables the protective coating 3 to be formed to cover the fine-uneven structure along the profile of the fine-uneven structure.

In ALD, deposition proceeds through the adsorption of monolayers and thus enables the formation of a uniform coating with a constant thickness without being affected by the profile of the base. ALD can, therefore, be suitable for deposition, or film formation, on the fine-uneven structure. The protective coating 3, which is formed along the profile of the fine-uneven structure, relieves discontinuous changes in refractive index in the fine-uneven structure, exhibiting consistent and continuous changes in refractive index. Also, the protective coating 3 undergoes an adsorption reaction with the OH groups in the surface of the base to form covalent bonds with the base, resulting in advantageous high adhesion. Since monolayers are deposited one by one, the resulting coating is dense and has high gas barrier properties that suppress the permeation of gases containing water vapor. Furthermore, the protective coating 3, which covers the fine-uneven structure, suppresses the permeation of gases over the entire region of the fine-uneven structure.

When the protective coating 3 is formed of silicon oxide film, the precursor of the raw material gas may be tris(dimethylamino)silane (TDMAS), which is a material of amino silane-based gases, tetraethoxysilane (TEOS), or silicon tetrachloride. When aluminum oxide is used, the precursor of the raw material gas may be trimethylaluminum (TMA). The precursor of the raw material gas can be selected as appropriate according to the material to be used. Also, the precursor used for oxidation can be H₂O or ozone. Ozone is advantageous for reducing deposition temperature. From the viewpoint of reducing temperature, plasma-enhanced ALD (PEALD) using plasma may be applied. When resin is used as the base 2, as in the present embodiment, PEALD, which can reduce deposition temperature, is also suitable.

When the protective coating 3 is formed of silicon nitride film, the precursor of the raw material gas may be the same precursor as for silicon oxide, and ammonia gas or nitrogen gas may be used as the precursor for nitriding. When titanium nitride is used, the precursor of the raw material gas may be tetrakis(dimethylamino)titanium (TDMAT) or titanium tetrachloride. As with the case of oxide films, when the protective coating 3 is formed of nitride film, the precursor of the raw material gas can be selected as appropriate according to the material to be used.

The carbon content of the protective coating 3 varies among the surface layer 3a, the internal portion 3b, and the interface layer 3c. This can be achieved by controlling the times of the (a)-(d) ALD cycle. To achieve a higher carbon content in the surface layer 3a than the internal portion 3b, the duration of step (c) in the ALD cycle for the surface layer 3a can be shortened. Alternatively, the ALD cycle, which is typically completed at step (d), may be terminated at step (b) to give the surface layer 3a a higher carbon content than the internal portion 3b. When the carbon content in the surface layer 3a is higher, functional groups are exposed at the surface of the protective coating 3 to increase the contact angle with water, enhancing the resistance to water droplets. A higher carbon content may increase the light absorption of the coating. In such a case, the duration of step (c) can be increased, for example. The carbon content in the surface layer 3a can be determined in consideration of the desired contact angle and light absorption of the coating at the surface of the protective coating 3.

In some embodiments, the internal portion 3b of the protective coating 3 is dense from the viewpoint of the resistance to water droplets. To obtain such a dense portion, the duration of step (c) can be set so as to sufficiently oxidize or nitride the raw material gas in the ALD cycle for depositing the internal portion 3b. However, an excessively long duration reduces the productivity of the device. The duration of step (c) for depositing the internal portion 3b is determined in view of the density of the deposited film and the productivity of the device.

In some embodiments, the carbon content in the interface layer 3c of the protective coating 3 is controlled low in view of the adhesion to the fine-uneven structure. For this purpose, the duration of step (c) is set so as to sufficiently oxidize or nitride the raw material gas in the ALD cycle for depositing the interface layer 3c. Allowing for the expansion and contraction of the base 2 due to temperature, as described above, the carbon content in the interface layer 3c is not necessarily 0, and the duration of step (c) for depositing the interface layer 3c may be shortened. The duration of step (c) for depositing the interface layer 3c can be determined in view of the adhesion between the base 2 and the protective coating 3 and allowing for the expansion and contraction of the base 2 due to temperature.

The above description discloses a method in which the carbon content of the protective coating 3 is controlled in the surface layer 3a, the internal portion 3b, and the interface layer 3c by adjusting the duration of step (c) of the ALD cycle. To control the carbon content, the duration of steps (a), (b), and (d) may be adjusted as an alternative method. Alternatively, the durations of steps (a) to (d) may be adjusted independently of each other. These methods can also control the carbon content in the surface layer 3a, the internal portion 3b, and the interface layer 3c.

Forming the protective coating 3 by ALD enables the carbon content to be controlled in the surface layer 3a, the internal portion 3b, and the interface 3c, each throughout a continuous deposition process. Other deposition processes than ALD require depositing the interface layer 3c, followed by the internal portion 3b, and finally, the surface layer 3a, resulting in a three-step deposition process. ALD can control the carbon content in each layer or portion through a simple manner of controlling the durations of ALD cycles, having the advantage of restricting the scaling-up of the device. In addition, the carbon content in each layer or portion can be controlled by one-batch deposition. Thus, ALD offers the advantage of enabling a simple deposition process with a restricted increase in the number of deposition operations.

### Second Embodiment

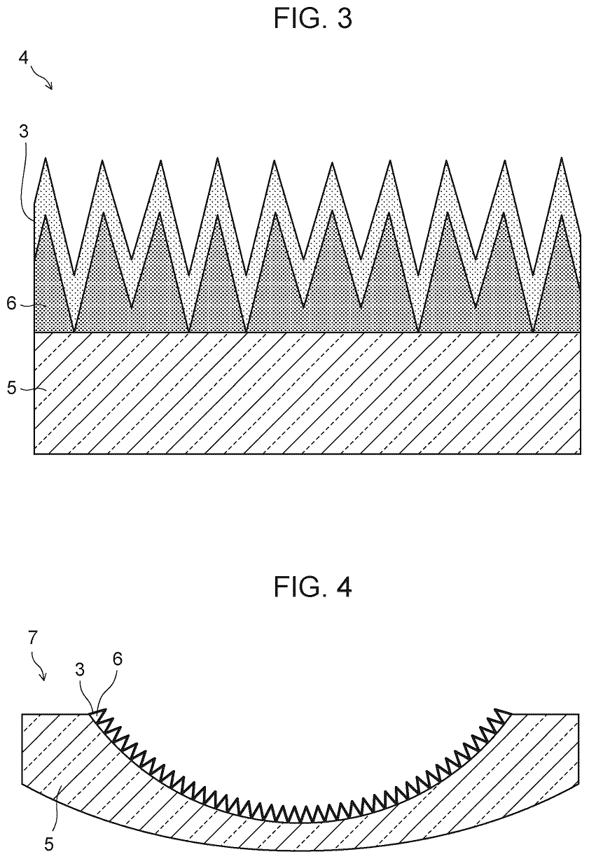

A second embodiment will now be described with reference to FIG. 3. In the second embodiment, differences from the first embodiment will mainly be described, and matters other than those described below can follow the first embodiment.

FIG. 3 is a sectional view of an optical member 4 according to the present embodiment. The optical member 4 includes a base 5 with light transparency (light-transmitting base), a structural film 6 (structural layer) with a fine-uneven structure having a plurality of protrusions, and a protective coating 3.

### Optical Member

The fine-uneven structure has a plurality of protrusions that are formed so as to continuously reduce the refractive index from the respective bottoms (on the side in contact with the base 5) toward the tips (toward the surface), as in the first embodiment. Thus, an antireflection function is imparted to the surface of the optical member 4. Also, the fine-uneven structure is formed as a film (structural film) in the present embodiment. The fine-uneven Structure in film form can be formed by various methods, increasing the degree of freedom in selecting the base 5. In some of the embodiments using glass as the base 5, the fine-uneven structure is formed as a film.

### Base

The base 5 may be made of a light-transmitting glass. Such glasses include synthetic quartz and other optical glasses containing alkali metal elements, alkaline-earth metal elements, and/or boron. Exemplary glasses include barium flint glass, barium crown glass, borosilicate crown glass, lanthanum flint glass, lanthanum crown glass, and titanium flint glass. In addition, phosphate-based, fluoride-based, and fluorophosphate-based glasses are included.

### Formation of Structural Film

The structural film 6 defining the fine-uneven structure can be formed on the base 5 by applying a coating material containing aluminum oxide or aluminum onto the surface of the base 5, followed by heating to fix the applied material as a film, and then immersing the resulting structure in warm water. The application of the coating material containing aluminum oxide or aluminum may be performed by spin coating, in which the coating material is dropped onto the rotating base 5. Alternatively, a film containing aluminum oxide or aluminum may be formed by vapor deposition, sputtering, or the like.

### Modification of Second Embodiment

FIG. 4 is a sectional view of a lens 7 that is a modification of the second embodiment. Although the shape of the base 5 in FIG. 3 is flat, the base 5 is not limited to such a flat shape and may have a three-dimensional surface, as illustrated in FIG. 4. In other words, for the lens 7 with a three-dimensional surface, a structural film 6 with a fine-uneven structure can be provided on the base 5, followed by forming a protective coating 3 over the surface of the structural film 6. Furthermore, the protective coating 3 is formed by ALD, thereby allowing the precursor to adsorb onto the surface of the structural film 6 at which OH groups are exposed. Thus, when a fine-uneven structure is formed on a lens with a three-dimensional surface as well, the protective coating 3 can also be formed along the profile of the fine-uneven structure to provide a member with ensured adhesion and water resistance.

The optical member described in the first embodiment can also be applied to a lens with a three-dimensional surface.

While the above embodiments have described the present disclosure using optical members and a lens, the concepts disclosed may be applied to various uses, such as lens barrels to hold lenses, accessory members for imaging devices, imaging devices, and solar panels, without being limited to optical members.

### Evaluation of Examples and Comparative Examples

Table 1 presents the configurations of Examples and Comparative Examples of the optical member according to the present disclosure. These configurations are presented as examples and are not limiting, and the configuration and film formation method may be modified as appropriate. Examples and Comparative Examples were subjected to observation, measurements of their reflectance, carbon content, oxygen or nitrogen content, and contact angle, examination of adhesion, and environmental test. Evaluations were performed through the following examinations.

### Observation

The surface and cross section of each optical member were observed using a scanning electron microscope (SEM). The cross section of the optical member was taken by focused ion beam (FIB) work and observed using the SEM to evaluate the profile of the fine-uneven structure.

### Measurement of Reflectance

The reflectance of the optical member at the surface with the protective coating 3 was measured using a spectrophotometer for light with wavelengths ranging from 350 nm to 8000 nm, incoming at an angle of 5 degrees.

### Composition Measurement of Protective Coating 3

The carbon content and oxygen or nitrogen content of the protective coating 3 in the surface layer 3a, the internal portion 3b, and the interface layer 3c were measured by X-ray photoelectron spectroscopy (XPS). XPS, in which the escape depth of photoelectrons ranges from several angstroms to several nanometers, can analyze the composition at the top surface of the coating. In addition, an Ar ion or C60 ion gun may be used to analyze not only the top surface of the coating but also the interior. Using these methods presented here, the ratios of carbon content to oxygen or nitrogen content of the protective coating 3 in the surface layer 3a, the internal portion 3b, and the interface layer 3c were determined and evaluated.

### Measurement of Contact Angle

The contact angle of the surface of the optical member was measured by the sessile drop method specified in JIS R 3257:1999. In this measurement, an image of droplets placed on the surface of the protective coating was used to determine the contact angle.

### Examination of Adhesion

For evaluating the adhesion of the optical member, the fine-uneven structure was wiped, and the surface was examined by visual observation.

### Environmental Test

In the environmental test, the optical member was allowed to stand in an environmental test apparatus set at a temperature of 60° C. and a humidity of 80% for 100 hours, and the changes in appearance and reflectance before and after the test were evaluated.

### Example 1

In Example 1, polycarbonate resin was used as the light-transmitting base, and a fine-uneven structure was formed at the surface of the polycarbonate resin using a stamper (mold) with a fine-uneven structure. Then, silicon oxide was deposited by ALD to form a protective coating on the surface of the fine-uneven structure. The deposition was repeated 220 cycles at a deposition temperature of 120° C. using TDMAS as the precursor of the raw material gas and ozone as the oxidation gas, thus forming the protective coating with a thickness of about 50 nm.

In view of adhesion of the polycarbonate resin with the base, the duration of ozone gas feeding was shortened at the start of the deposition compared to the standard duration. At the end of the deposition, the duration of ozone gas feeding was also shortened compared to the standard duration to increase the percentage of functional groups, such as alkyl or methylene groups, exposed at the surface of the protective coating. Furthermore, the deposition was terminated after the completion of purging the fed raw material gas precursor (step (b) of the above-described ALD cycle) and before feeding ozone gas. When the surface of the optical member produced in Example 1 was observed using an SEM, a fine-uneven structure with a pitch less than or equal to the wavelengths of visible light was identified. Also, when the FIB-worked cross section was observed using the SEM, it was confirmed that the protective coating had been formed to cover the fine-uneven structure along the profile of the fine-uneven structure. The surface of the optical member was wiped, and the adhesion of the protective coating was examined. The adhesion was good with no peeling of the coating. Additionally, no changes in appearance or reflectance were observed after the environmental test.

When the protective coating of the optical member was formed, a polycarbonate flat test substrate was placed in the same batch, and the protective coating was formed over the test substrate as well. The test substrate covered with the protective coating was subjected to composition analysis of the surface layer and internal portion of the protective coating and its interface layer with the test substrate by XPS. The pitch of the fine-uneven structure is less than or equal to the wavelengths of visible light and smaller than the diameter of the area analyzed by XPS. Therefore, the compositions of the surface layer, internal portion, and interface layer of the protective coating over the fine-uneven structure are difficult to analyze accurately. Accordingly, the compositions of the surface layer, internal portion, and interface layer of the protective coating were obtained using the flat test substrate. The surface layer contained 14.5 at % of silicon, 7.6 at % of oxygen, and 77.9 at % of carbon. The internal portion contained 62.2 at % of silicon, 30.9 at % of oxygen, and 6.9 at % of carbon. The interface layer contained 53.1 at % of silicon, 26.2 at % of oxygen, and 20.7 at % of carbon. Analysis of the bonding state of the carbon indicates that most of the carbon is in a state bound to hydrogen (in a state of functional groups such as alkyl or methylene groups). However, XPS cannot detect the photoelectron spectrum of hydrogen, and thus, the hydrogen content is not presented. When the contact angle of the test substrate was measured, it was 97°, exhibiting water repellency.

### Example 2

Example 2 used a phosphate-based glass as the light-transmitting base. With the glass on a turntable, a coating material containing aluminum oxide or aluminum was dropped around the center of the glass. Thus, spin coating was performed at 3000 rpm for 30 seconds. The spin-coated glass was then heated at 210° C. for 3 hours. The heat-treated glass was immersed in warm water of 65° C. to 85° C. in temperature for 30 minutes to form a fine-uneven structure containing aluminum and having a pitch less than or equal to the wavelengths of visible light over the surface of the glass. Then, silicon oxide was deposited to form a protective coating in the same manner as in Example 1.

When the surface of the optical member produced in Example 2 was observed using an SEM, a fine-uneven structure with a pitch less than or equal to the wavelengths of visible light was identified. Also, when the FIB-worked cross section was observed using the SEM, it was confirmed that the protective coating had been formed to cover the fine-uneven structure along the profile of the fine-uneven structure. The surface of the optical member was wiped, and the adhesion of the protective coating was examined. The adhesion was good with no peeling of the coating. Additionally, no changes in appearance or reflectance were observed after the environmental test.

When the protective coating of the optical member was formed, a glass flat test substrate was placed in the same batch, and the protective coating was formed over the test substrate as well. The test substrate covered with the protective coating was subjected to composition analysis of the surface layer and internal portion of the protective coating and its interface layer with the glass by XPS. The surface layer contained 16.5 at % of silicon, 8.1 at % of oxygen, and 75.4 at % of carbon. The internal portion contained 62.5 at % of silicon, 31.0 at % of oxygen, and 6.5 at % of carbon. The interface layer contained 58.2 at % of silicon, 29.1 at % of oxygen, and 12.7 at % of carbon.

When the contact angle of the test substrate was measured, it was 95°, exhibiting water repellency.

### Comparative Example 1

In Comparative Example 1, the production process of the optical member in Example 1 was changed in such a manner that the duration of ozone gas feeding at the end of the deposition of the protective coating was set at the standard duration, and the deposition was terminated after the completion of purging following the ozone gas feeding (after step (d) of the above-described ALD cycle). Other steps in the production process were the same as in Example 1.

When the surface of the optical member produced in Comparative Example 1 was observed using an SEM, a fine-uneven structure with a pitch less than or equal to the wavelengths of visible light was identified. Also, when the FIB-worked cross section was observed using the SEM, it was confirmed that the protective coating had been formed to cover the fine-uneven structure along the profile of the fine-uneven structure. The optical member was wiped, and the adhesion of the coating was examined. The adhesion was good with no peeling. When the appearance was examined after the environmental test, dried traces of water droplets and a slight change in reflectance were observed.

When the protective coating of the optical member was formed, a polycarbonate flat test substrate was placed in the same batch, and the protective coating was formed over the test substrate as well. The test substrate covered with the protective coating was subjected to composition analysis of the surface layer and internal portion of the protective coating and its interface layer with the test substrate by XPS. The surface layer contained 62.6 at % of silicon, 30.8 at % of oxygen, and 6.6 at % of carbon. The internal portion contained 62.3 at % of silicon, 31.3 at % of oxygen, and 6.4 at % of carbon. The interface layer contained 55.2 at % of silicon, 28.1 at % of oxygen, and 16.7 at % of carbon. When the contact angle of the test substrate was measured, it was 60°.

### Comparative Example 2

In Comparative Example 2, the production process of the optical member in Example 1 was changed in such a manner that the protective coating was formed by applying a silicon-based water repellent. Other steps in the production process were the same as in Example 1.

When the surface of the optical member produced in Comparative Example 2 was observed using an SEM, a fine-uneven structure with a pitch less than or equal to the wavelengths of visible light was identified. Also, when the FIB-worked cross section was observed using the SEM, it was confirmed that the protective coating had been formed to cover the fine-uneven structure along the profile of the fine-uneven structure. When the optical member was wiped and the adhesion was examined, the peeling of the protective coating was observed. When the appearance was examined after the environmental test, a pinhole and a slight change in reflectance were observed.

When the protective coating of the optical member was formed, a polycarbonate flat test substrate was placed in the same batch, and the protective coating was formed over the test substrate as well. The test substrate covered with the protective coating was subjected to composition analysis of the surface layer and internal portion of the protective coating and its interface layer with the test substrate by XPS. The surface layer contained 20.7 at % of silicon, 26.1 at % of oxygen, and 53.2 at % of carbon. The internal portion contained 23.5 at % of silicon, 25.6 at % of oxygen, and 50.9 at % of carbon. The interface layer contained 24.2 at % of silicon, 25.3 at % of oxygen, and 50.5 at % of carbon. When the contact angle of the test substrate was measured, it was 91°.

The carbon and oxygen contents in the Examples and Comparative Examples are presented in Table 1. Also, Table 2 presents the ratios of carbon content to oxygen content, the measurement results of contact angle, and other test results.

TABLE 1

| | Carbon content/at % | | | Oxygen content/at % | | |
|---|---|---|---|---|---|---|
| | Surface | Internal | Interface | Surface | Internal | Interface |
| | layer | portion | layer | layer | portion | layer |
| Example 1 | 77.9 | 6.9 | 20.7 | 7.6 | 30.9 | 26.2 |
| Example 2 | 75.4 | 6.5 | 12.7 | 8.1 | 31.0 | 29.1 |
| Comparative | 6.6 | 6.4 | 16.7 | 30.8 | 31.3 | 28.1 |
| Example 1 | | | | | | |
| Comparative | 53.2 | 50.9 | 50.5 | 26.1 | 25.6 | 25.3 |
| Example 2 | | | | | | |

TABLE 2

| | Carbon content/Oxygen content | | | | | |
|---|---|---|---|---|---|---|
| | Surface | Internal | Interface | Contact | | Environmental |
| | layer | portion | layer | angle/° | Adhesion | test |
| Example 1 | 10.25 | 0.22 | 0.79 | 97 | Good | Good |
| Example 2 | 9.31 | 0.21 | 0.44 | 95 | Good | Good |
| Comparative | 0.21 | 0.20 | 0.59 | 60 | Good | Not Good |
| Example 1 | | | | | | |
| Comparative | 1.93 | 2.16 | 2.00 | 91 | Not | Not Good |
| Example 2 | | | | | Good | |

Table 2 suggests that adhesion is related to the ratio of carbon content to oxygen content in the interface layer. The lower the carbon content in the interface layer, that is, the larger the amount of protective coating bound to hydroxy groups in the surface of the fine-uneven structure, the higher the adhesion of the protective coating. The environmental test showed a relationship with the ratios of carbon content to oxygen content in the surface layer and the internal portion. When the carbon content is higher in the surface layer and lower in the internal portion, the environmental test results are good. This is because when the surface layer has a higher carbon content, functional groups such as alkyl or methylene groups are exposed at the surface, leading to an increased contact angle to impart resistance to water droplets. In contrast, when the carbon content is lower, the contact angle decreases, and the resistance to water droplets is degraded, leaving dried traces of water droplets. Thus, a higher carbon content is beneficial in the surface layer. In contrast, higher carbon content in the internal portion hinders the formation of dense silicon oxide, resulting in water vapor permeation. Thus, a lower carbon content is beneficial in the internal portion. Specifically, the desirable approximate ratio of carbon content to oxygen content is 0.5 or more in the surface layer, 1.6 or less in the internal portion, and 1.0 or less in the interface layer.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-050586 filed Mar. 26, 2024, which is hereby incorporated by reference herein in its entirety.

What is claimed is:

1. A member comprising:
a base having a surface with an uneven structure; and
a layer containing an oxide or a nitride over the uneven structure of the base, the layer having a higher carbon content at a surface thereof than on an inside thereof.

2. The member according to claim 1, wherein the uneven structure has a pitch of 800 nm or less.

3. The member according to claim 1, wherein the layer satisfies a relationship: [Cₛ]/[Bₛ]≥0.5, wherein [Cₛ] represents the carbon content at the surface of the layer, and [Bₛ] represents an oxygen or nitrogen content at the surface of the layer.

4. The member according to claim 1, wherein the layer satisfies a relationship: [Cₙ]/[Bₙ]≤1.6, wherein [Cₙ] represents the carbon content on the inside of the layer, and [Bₙ] represents an oxygen or nitrogen content on the inside of the layer.

5. The member according to claim 1, wherein an interface between the uneven structure and the layer satisfies a relationship: [Cₖ]/[Bₖ]≤1.0, wherein [Cₖ] represents the carbon content at the interface, and [ₖr] represents an oxygen or nitrogen content at the interface.

6. The member according to claim 1, wherein the layer contains silicon oxide.

7. The member according to claim 1, wherein the base is a light-transmitting base with the uneven structure.

8. The member according to claim 7, wherein the light-transmitting base is made of resin.

9. The member according to claim 1, wherein the base includes a light-transmitting base, and a structural layer with the uneven structure on the light-transmitting base.

10. The member according to claim 9, wherein the structural layer contains aluminum or aluminum oxide.

11. The member according to claim 9, wherein the light-transmitting base is made of glass.

12. The member according to claim 1, wherein a height of the uneven structure is between 100 nm and 2000 nm.

13. The member according to claim 1, wherein the uneven structure has a pitch of 800 nm or less, and a height of the uneven structure is between 100 nm and 2000 nm.

14. The member according to claim 1, wherein the layer contains one of aluminum oxide, tantalum oxide, titanium oxide, niobium oxide, zirconium oxide, yttrium oxide and indium tin oxide.

15. The member according to claim 1, wherein the layer contains one of silicon nitride, titanium nitride, and aluminum nitride.

16. The member according to claim 1, wherein the base contains one of polycarbonate resin, acrylate resin, and polyolefin resin.

17. A method for manufacturing a member, comprising:
preparing a base having a surface with an uneven structure; and
forming a layer by atomic layer deposition over the surface of the uneven structure such that the layer has a higher carbon content at a surface thereof than on an inside thereof.

18. The method according to claim 17, wherein the layer contains an oxide or a nitride.

19. The method according to claim 17, wherein a height of the uneven structure is between 100 nm and 2000 nm.

20. The method according to claim 17, wherein a height of the uneven structure is between 100 nm and 2000 nm.
